(19) United States
(12) Patent Application Publication
(10) Pub. No.: US 2024/0404780 A1
(43) Pub. Date: Dec. 5, 2024

(54) SEMICONDUCTOR PROCESSING APPARATUS

(71) Applicant: Hitachi High-Tech Corporation, Tokyo (JP)

(72) Inventors: Masahiro KAMIGAKI, Tokyo (JP); Motohiro TAKAHASHI, Tokyo (JP); Masaki MIZUOCHI, Tokyo (JP); Masashi FUJITA, Tokyo (JP); Takumi NAGAYAMA, Tokyo (JP)

(73) Assignee: Hitachi High-Tech Corporation, Tokyo (JP)

(21) Appl. No.: 18/732,344

(22) Filed: Jun. 3, 2024

(30) Foreign Application Priority Data
Jun. 5, 2023 (JP) 2023-092089

(51) Int. Cl. H01J 37/18; G03F 7/00; H01J 37/304; H01L 21/67; H01L 21/687

(52) U.S. Cl. CPC H01J 37/185; G03F 7/70525; G03F 7/7075; G03F 7/70841; G03F 7/709; H01J 37/304; H01L 21/67201; H01L 21/68707; H01J 2237/006

(57) ABSTRACT

A plurality of load lock chambers are provided, a predetermined valve device is controlled such that the valve device is not operated during wafer processing, a signal for permitting operation of the predetermined valve device is transmitted at a timing when the wafer processing is completed, and the valve device is operated based on the signal. Thus, while a processed wafer and an unprocessed wafer are exchanged between one load lock chamber and a processing chamber, an operation sequence of the entire semiconductor processing apparatus is controlled such that a predetermined valve device in the other load lock chamber is operated, and thus vibration does not occur during the operation of an electron optical system, thereby reducing a waiting time.

### CLAIM OF PRIORITY

The present application claims priority from Japanese Patent Application JP 2023-092089 filed on Jun. 5, 2023, the content of which is hereby incorporated by reference into this application.

### BACKGROUND OF THE INVENTION

### 1. Field of the Invention

The present invention relates to a semiconductor processing apparatus that performs observation using a charged particle beam, processing (such as sputtering), and pattern exposure using light of a semiconductor wafer, and particularly relates to a semiconductor processing apparatus that has a higher throughput than that of the related art.

### 2. Description of Related Art

Charged particle beam devices have been used to measure fine patterns and inspect defects in semiconductor devices. Charged particle beam devices have been strongly required to improve the precision of pattern measurement and inspection, as well as to increase the number of wafers that can be processed per hour (hereinafter referred to as “throughput”).

A charged particle beam device needs to observe samples in a high vacuum environment, and thus a load lock chamber (hereinafter referred to as LC) for connecting the atmospheric pressure environment outside the device and a sample chamber (hereinafter referred to as SC) in a high vacuum environment is necessary. To improve a throughput, in parallel to processing for irradiating a sample with a charged particle beam in the SC, an operation of carrying a wafer in atmospheric pressure environment into the LC and performing vacuum exhaust is performed to carry a sample to be processed next into the SC.

To increase a throughput, it is effective to minimize a time (waiting time) for which measurement, inspection, and the like are not performed within the device. On the other hand, to cope with the miniaturization of semiconductor devices in recent years, demands for resolution and reproducibility in pattern measurement and inspection have become extremely high, and when the vibrations generated due to the movement of movable parts within the device are transmitted to an electron optical system, a relative displacement occurs between an electron beam of a scanning electron microscope (SEM) and a sample due to the vibration of the electron beam or the sample while the vibration is occurring and until the vibration converges, and vibrational noise is superimposed on an image, which leads to a concern that it is not possible to meet specifications required for pattern measurement and inspection.

As a method of achieving both precision of pattern measurement, inspection, and the like, and a throughput, JP2004-158616A discloses an exposure apparatus that stops conveyance operations such as robot operations and valve operations at a timing when mechanical vibrations and disturbance magnetic fields are not desirable to perform an exposure operation and wafer conveyance in parallel, thereby improving a throughput.

### SUMMARY OF THE INVENTION

According to the technology disclosed in JP2004-158616A, it is possible to perform an operation of an electron optical system and a wafer conveyance operation in parallel while satisfying performance required for pattern measurement and inspection. However, there is a problem in that an SEM cannot be operated during the operation of a mechanism generating vibration, such as a pipe opening/closing valve for evacuation of an LC, resulting in a waiting time and a reduction in throughput.

The waiting time is caused by, for example, vibrations accompanied by the operation of the pipe opening/closing valve connected to a vacuum pump for controlling the pressure of the LC or the operation of a shutter (gate valve) that opens and closes a sample carry-in port for the LC, and a reduction in the waiting time is required to improve the throughput.

An object of the invention is to provide a semiconductor processing apparatus capable of reducing the number of vibrations that occur during processing of a semiconductor wafer and reducing a waiting time.

A configuration of the invention for achieving the above-described object is as follows.

A semiconductor processing apparatus according to an aspect of the invention is a semiconductor processing apparatus including a sample chamber that includes a processing mechanism for processing a semiconductor wafer therein, a plurality of load lock chambers that carry the semiconductor wafer into the sample chamber, and a sample exchange mechanism that exchanges semiconductor wafers between the sample chamber and each of the plurality of load lock chambers, in which the semiconductor processing apparatus includes a control mechanism that controls operations of mechanisms of the plurality of load lock chambers so that an operation of a mechanism accompanied by an operation that generates vibration is performed in a load lock chamber in which the semiconductor wafer is not exchanged among the plurality of load lock chambers at a timing when one of the plurality of load lock chambers is exchanging the semiconductor wafer with the sample chamber.

According to the invention, it is possible to provide a semiconductor processing apparatus capable of reducing the number of vibrations that occur during processing of a semiconductor wafer and reducing a waiting time.

### BRIEF DESCRIPTION OF THE DRAWINGS

FIG. 1 is a configuration diagram of a charged particle beam device according to a first embodiment;

FIG. 2 is a configuration diagram of a charged particle beam device of the related art;

FIG. 3 is a flowchart showing an example of a flow of wafer conveyance in the charged particle beam device of the related art;

FIG. 4 is a timing chart showing a device operation when the charged particle beam device of the related art is controlled using a method shown in FIG. 3;

FIG. 5 is a flowchart showing an example of a flow of wafer conveyance in the charged particle beam device according to the first embodiment;

FIG. 6 is a timing chart showing a device operation when the charged particle beam device according to the first embodiment is controlled using a method shown in FIG. 5;

FIG. 7 is a timing chart showing a device operation when the charged particle beam device according to the first embodiment is controlled using the method shown in FIG. 5 and a time required for evacuation of an LC is long; and

FIG. 8 is a timing chart showing a device operation when the charged particle beam device according to the first embodiment is controlled using the method shown in FIG. 5 and a time required for wafer processing is short.

### DESCRIPTION OF EMBODIMENTS

An embodiment of the invention will be described below with reference to the drawings and the like. The following description shows specific examples of the contents of the invention, the invention is not limited to the description, and various changes and modifications can be made by those skilled in the art within the scope of the technical idea disclosed in the specification. In all of the drawings for describing the invention, parts having the same functions are given the same reference numerals, and repeated description thereof may be omitted.

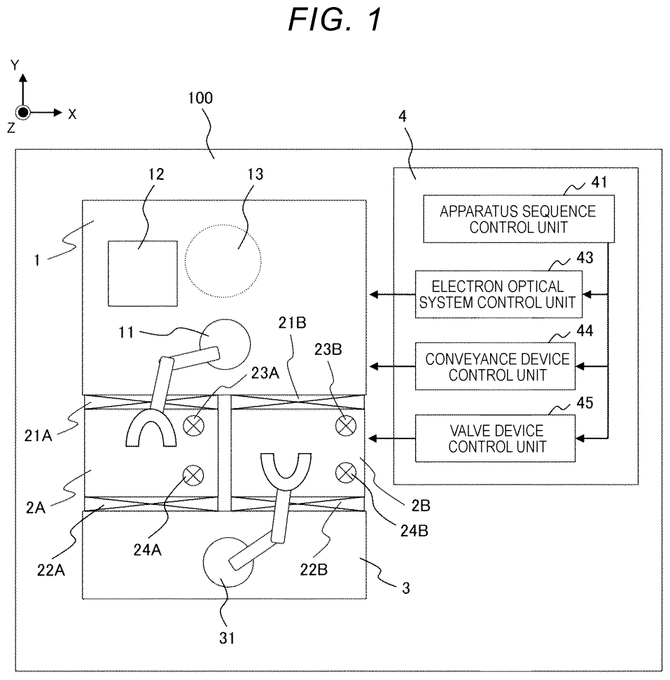

Referring to FIG. 1 and FIGS. 5 to 8, an embodiment of a charged particle beam device will be described as an example of a semiconductor processing apparatus to which the invention is applied.

FIG. 1 is a configuration diagram showing a semiconductor measurement device according to an embodiment of the disclosure.

A semiconductor measurement device 100, which is an embodiment of a charged particle beam device according to the disclosure, is a device that irradiates a wafer with a charged particle beam and measures a pattern formed on the wafer. The semiconductor measurement device 100 includes a sample chamber 1 (hereinafter referred to as SC1), a load lock chamber A: LC 2A (hereinafter referred to as LC-A), a load lock chamber B: LC 2B (hereinafter referred to as LC-B), a mini-environment 3, and a computer system 4.

The SC1 includes a robot 11 that conveys a wafer, a stage device 12 that positions the wafer inside an SC, and a column 13 that is equipped with an electron gun that irradiates the wafer with a charged particle beam.

The LC-A and the LC-B include gate valves 21A and 21B that open and close an opening between an LC and the SC, gate valves 22A and 22B that open and close an opening between the LC and the mini-environment, valves 23A and 23B that open and close a pipe connected to a roughing vacuum pump, and valves 24A and 24B that open and close a pipe connected to a turbo molecular pump (hereinafter referred to as TMP).

The computer system 4 includes a control unit 41 that controls an operation sequence of the entire device, an electron optical system control unit 43 that receives a command from the control unit 41 and controls irradiation with a charged particle beam, a conveyance device control unit 44 that controls robots 11 and 31 related to wafer conveyance and the stage device 12, and a valve device control unit 45 that controls the pressures of the LC-A and the LC-B. Although there is one robot 11 in FIG. 1, two or more robots may be used.

The mini-environment 3 includes the robot 31 that conveys wafers within the mini-environment.

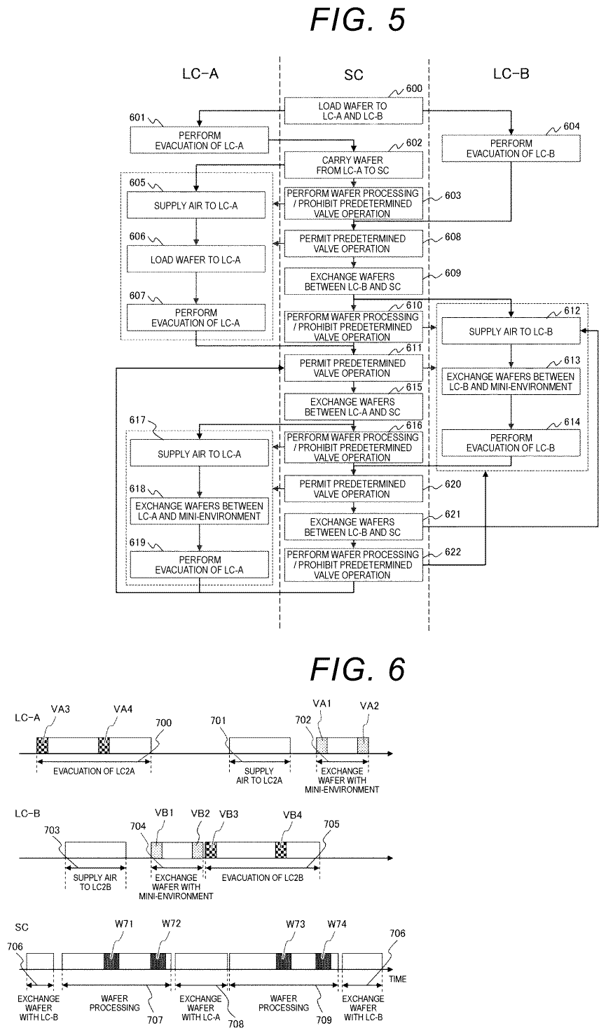

FIG. 5 is a flowchart showing an example of a flow of wafer conveyance in the semiconductor measurement device 100 to which the invention is applied. Operations based on the flowchart of FIG. 5 are as follows.

Step 600: It is confirmed that pressures inside the LC-A and the LC-B are near atmospheric pressure, the gate valves 22A and 22B are opened, and a first wafer and a second wafer are carried into the LC-A and the LC-B using the robot 31.

Step 601: Evacuation of the LC 2A is performed by closing the gate valve 22A after step 600 is completed. The valve 23A that opens and closes the pipe connected to the roughing vacuum pump and the valve 24A that opens and closes the pipe connected to the TMP operate at an appropriate timing.

Step 604: Evacuation of the LC-B is performed by closing the gate valve 22B. Here, the valves 23B and 24B operate at an appropriate timing. Here, as a method of setting an appropriate timing, for example, a method of measuring the pressure inside the LC-B and performing a valve operation at a timing when the pressure falls below a preset predetermined pressure or at a timing when a preset predetermined time has elapsed is effective. Here, it is desirable that the pressure or time be set within a range that will not be affected by foreign matter scattering due to a gas flow inside the LC-B.

Step 602: When the evacuation of the LC-A is completed, the gate valve 21A is opened, the first wafer within the LC-A is conveyed onto the stage device 12 of the SC1 using the robot 11.

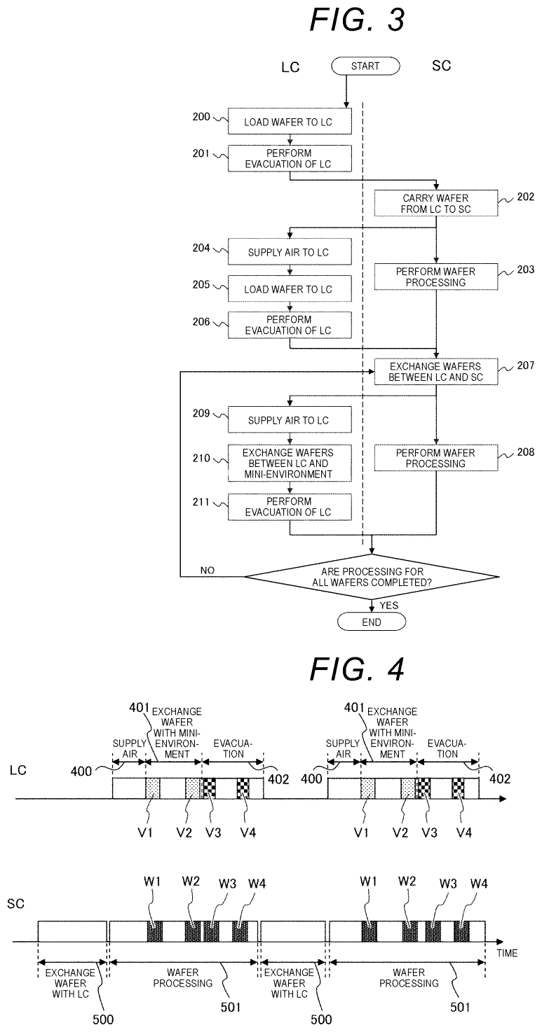

Step 603: After step 602 is completed, wafer processing is performed on the first wafer in the same manner as in step 203 in FIG. 3.

During the wafer processing, a signal for prohibiting a predetermined valve operation (for example, an operation of closing the gate valve 22A and/or an operation of opening the valve 23A) of the LC-A that operates in steps 605, 606, and 607 is transmitted from the device sequence control unit 41 to the valve device control unit 45.

A method is effective in which predetermined valves whose operation is prohibited are stored as information in a measurement recipe file that defines processing contents such as measurement points on a wafer, and are stored in the computer system 4 at a timing when the measurement recipe file is read. Another effective method is a method in which a device user selects a valve whose operation is to be prohibited during wafer processing on a device graphic interface (GUI) and reads the information into the computer system 4.

Step 605: After step 602 is completed, the gate valve 21A is closed, and a predetermined gas, such as nitrogen, is supplied to the LC-A in parallel with step 603 to increase the pressure of the LC-A to near atmospheric pressure.

Step 608: After both the wafer processing in step 603 and step 604 are completed, the conveyance device control unit 44 transmits a signal for permitting a valve operation of the LC-A prohibited in step 603 to the device sequence control unit 41.

Step 606: When the pressure inside the LC-A is increased to near atmospheric pressure, the gate valve 22A is opened, and a third wafer is conveyed into the LC-A using the robot 31. Here, when the operation of the gate valve 22A is prohibited by the valve device control unit 45, the operation is waited for until an operation permission signal is given in step 608.

Step 607: The gate valve 22A is closed, and evacuation of the LC-A is performed. When the evacuation of the LC-A is performed, the valves 23A and 24A are operated at an appropriate timing. For example, a method similar to that described in step 604 is effective as a method of setting an appropriate timing. Here, when the operation of the gate valve 22A or the valves 23A and 24A is prohibited by the valve device control unit 45, the operation of the corresponding valve is waited for until an operation permission signal is given in step 608.

Step 609: The gate valve 21B is opened, and the first wafer on the stage device 12 of the SC1 and the second wafer in the LC-B are exchanged using the robot 11.

Step 610: Wafer processing is performed on the second wafer in the same manner as in step 603. Here, a signal for prohibiting a predetermined value operation (for example, an operation of closing the gate valve 22B and an operation of opening the valve 23B) of the LC-B that operates in steps 612, 613, and 614 is transmitted from the device sequence control unit 41 to the valve device control unit 45.

Step 612: After step 609 is completed, the gate valve 21B is closed, and the pressure of the LC-B is increased to near atmospheric pressure in parallel with step 610.

Step 611: Similarly to step 608, when the wafer processing in step 610 and step 607 are completed, the conveyance device control unit 44 transmits a signal for permitting a predetermined valve operation of the LC-B prohibited in step 610 to the device sequence control unit 41.

Step 613: When the pressure of the LC-B is increased to near atmospheric pressure, the gate valve 22B is opened, the first wafer (measured wafer) in the LC-B is carried out of the device using the robot 31, and at the same time, a fourth wafer (unmeasured wafer) is carried into the LC-B using the robot 31. Here, when the operation of the gate valve 22B is prohibited, the operation of the corresponding valve is waited for until an operation permission signal is given in step 611.

Step 614: The gate valve 22B is closed, and evacuation of the LC-B is performed.

Step 615: The gate valve 21A is opened, and the second wafer on the stage device 12 of the SC1 and the third wafer in the LC-A are exchanged using the robot 11.

Step 616: The same processing as step 603 is performed.

Step 617: Similarly to step 605, the pressure of the LC-A is increased to near atmospheric pressure.

Step 618: When the pressure of the LC-A is increased to near atmospheric pressure, the gate valve 22A is opened, the second wafer (measured wafer) in the LC-A is carried out of the device using the robot 31, and at the same time, a fifth wafer (unmeasured wafer) is carried into the LC-A using the robot 31. Here, when the operation of the gate valve 22A is prohibited, the operation of the corresponding valve is waited for until an operation permission signal is given in step 620.

Step 619: Similarly to step 607, evacuation of the LC-A is performed.

Step 620: The same processing as step 608 is performed.

Step 621: The same processing as step 609 is performed.

Step 622: The same processing as step 610 is performed.

Thereafter, the processing returns to step 611 as soon as both the operations in step 622 and step 619 are completed, and the wafer processing can be performed one after another.

FIG. 6 is an example of a timing chart showing device operations in the SC1, the LC 2A, and the LC 2B of the semiconductor measurement device 100. The timing chart shows an operation of processing two wafers. The horizontal axis represents time, and SC, LC-A, and LC-B indicate the SC1, the LC 2A, and the LC 2B in FIG. 1, respectively. Three time axes are displayed in synchronization.

The timing chart is an example of a case where an operation of closing the gate valves 22A and 22B and an operation of opening the valves 23A and 23B are prohibited during wafer processing in steps 603, 610, and 616.

Times 700, 701, and 702 required to evacuate the LC 2A, supply air, and exchange a wafer with the mini-environment represent times required to perform steps 619, 617, and 618, respectively. 700 includes operating times VA3 and VA4 of the valves 23A and 24A. 702 includes opening/closing operation times VA1 and VA2 of the gate valve 22A.

Times 703, 704, and 705 required to supply air to the LC 2B, exchange a wafer with the mini-environment, and perform evacuation represent times required to perform steps 612, 613, and 614, respectively. 705 includes operating times VB3 and VB4 of the valves 23B and 24B. 704 includes opening/closing operation times VB1 and VB2 of the gate valve 22B.

A time 706 required to exchange a wafer with the LC 2B, wafer processing times 707 and 709, and a time 708 required to exchange a wafer with the LC 2A represent times required for steps 621, 622, 616, and 615, respectively.

Along with the operating times VA4, VB1, VB4, and VA1 of the valves that operate in parallel to wafer processing, waiting times W71, W72, W73, and W74 occur in the wafer processing, respectively.

As compared with FIG. 4, which will be described later, the number of times the valve device operates during wafer processing is reduced, a waiting time can be reduced, and thus it can be understood that a throughput is improved.

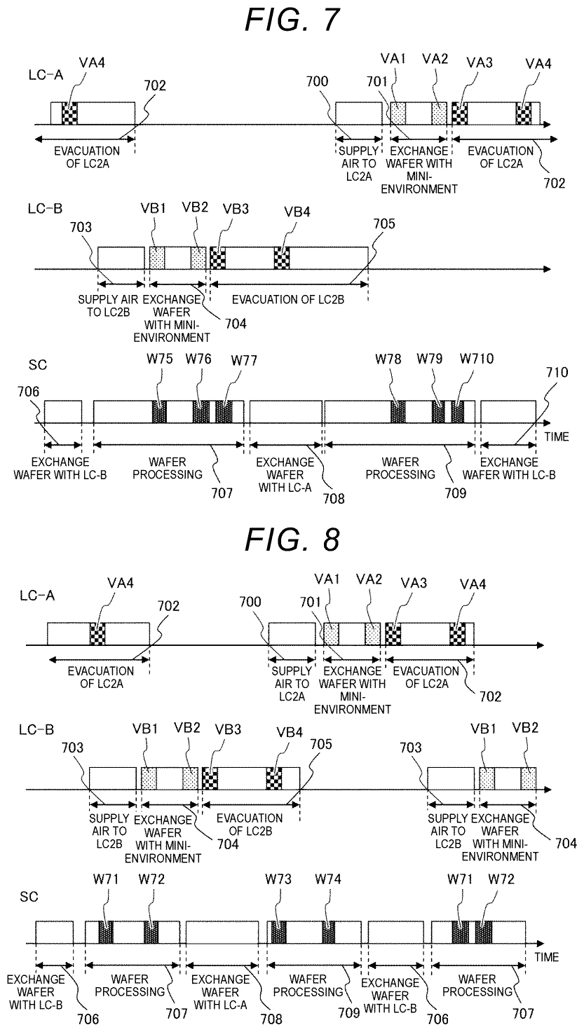

FIG. 7 shows an example of a timing chart when a long period of time is required to evacuate the LC in the semiconductor measurement device 100 to which the invention is applied.

For example, when the performance of a vacuum pump provided near the device is low, or when a wafer being processed generates a large amount of outgas, a long period of time is required for evacuation.

The next wafer processing cannot be started unless both the previous wafer processing and the evacuation of the LC including the next wafer to be processed are completed, and thus, when the completion of the evacuation is later than the completion of the wafer processing, a throughput will be reduced.

Here, a reduction in throughput can be avoided by setting operations of valves whose operation is prohibited during wafer processing to, for example, the operations of the valves 24A and 24B. FIG. 7 is a timing chart when the valves 24A and 24B are not operated during wafer exchange.

In the wafer processing times 707 and 709, waiting times W75, W76, W77, W78, W79, and W710 occur due to the valve operations of VB1, VB2, VB3, VA1, VA2, and VA3, respectively. However, there is no time to wait for the evacuation of the LC-A and the LC-B to be completed after the wafer processing times 707 and 709, and thus a reduction in throughput due to a delay in evacuation can be avoided. As compared with a timing chart of a charged particle beam device of the related art shown in FIG. 4, which will be described later, it can be understood that the number of times that a waiting time occurs during wafer processing can be reduced and a throughput is improved.

FIG. 8 shows a timing chart when a time required for wafer processing is short in the semiconductor measurement device 100.

For example, when there are few locations where pattern measurement is required in the semiconductor measurement device, a time required for wafer processing is shorter than when many locations are measured. Here, similarly to the case described with reference to FIG. 7, when evacuation of the LC including a next wafer to be carried into the SC is delayed, a throughput will be reduced.

Even when a wafer processing time is short, for example, valve operations similar to those shown in FIG. 6 are prohibited during wafer processing, and thus it is possible to reduce the number of times that a waiting time occurs during wafer processing as compared with that in the related art, and a throughput is improved.

As an effect of the invention in which a plurality of LCs are provided, even when a wafer processing time is short, it is possible to complete evacuation of the LC including a next wafer to be carried into the SC, and thus a throughput can be improved.

A method of prohibiting operations of specific valves during wafer processing in the SC has been described in steps 603 and 610 in FIG. 5, but as described so far, a time required for evacuation of the LC may vary depending on the type of wafer, or a time required for wafer processing may vary.

As a method of maximizing a throughput even in such cases, a method of determining an operation timing of the valve device from times required for evacuation of the LC and wafer processing will be described.
A time Ta required to supply air to the LC, a time Tm required to exchange wafers between the mini-environment and the LC, and a time Tc required to exchange wafers between the LC and the SC are given as parameters. Since such times do not vary greatly depending on the type of wafer, such times are determined by measurement in advance, for example, and stored in the computer system 4 as parameters. A method of measuring the parameters at any time during actual use of the device and storing an average time thereof as a parameter is also effective.
A wafer is carried from the LC 2A to the SC1.
A time Tw required for wafer processing of the wafer carried into the SC1 is given as a parameter. For example, from the sum (MAM time) of a time required to measure one location of a pattern on the wafer and a time required for the stage device to move to the location, and from information indicating how many locations of the pattern are to be measured, it may be predicted as MAM time*measurement location=Tw. When creating a measurement recipe file that defines processing contents such as measurement points on the wafer, a method of calculating and predicting Tw within the computer system 4 by predicting a MAM time from the number of measurement points on the wafer and a moving distance of the stage device 12 is also effective.
An evacuation time Te of a next wafer to be carried into the LC 2A is given as a parameter. For example, a time Te1 from the opening of the valve 23A to the opening of the valve 24A and a time Te2 from the opening of the valve 24A to when the pressure drops to a predetermined pressure are measured from a preliminary experiment, and Te=Te1+Te2 may be given. Here, as a method of setting the predetermined pressure, for example, a method of measuring the pressure inside the LC 2A and the pressure inside the SC1 and setting a difference between the pressures to be equal to or less than a predetermined value (for example, 0.0001 Pa) is effective.
From the time parameters given so far, valves that are desired to be operated during wafer exchange between the LC and the SC, that is, valves that are prohibited from operating during wafer processing, are determined. An example of the method will be described below.
Case of Ta+Tm+Te>2Tw+Tc: Since the completion of evacuation is later than that of wafer processing, evacuation of the LC is preferentially performed without setting a valve whose operation is to be prohibited during wafer processing.
Case of Te>Tc+Tw: When an operation of opening the valve 23A is prohibited during wafer processing, the completion of evacuation will be later than that of wafer processing, and thus an operation of opening the valve 24A is prohibited during the wafer processing.
Case of Tm+Te>Tc+Tw: When an operation of opening the gate valve 22A is prohibited during wafer processing, the completion of evacuation will be later than that of the wafer processing, and thus other valve operations are prohibited. For example, an operation of closing the gate valve 22A and an operation of opening the valve 23A are prohibited.

Even when a wafer is carried from the LC 2B to the SC1 and wafer processing is performed, an appropriate valve operation timing can be selected using the above-described method.

The time Te required for the evacuation of the LC and the time Tw required for the wafer processing may be corrected sequentially based on the actual data of device operation, or may be given as parameters in advance according to the type of wafer.

As described above, a valve operation timing is set such that the completion of evacuation is not later than the completion of wafer processing, and thus it is possible to improve a throughput while minimizing a waiting time accompanied by a valve operation.

It is effective that processing for determining an operation timing of the valve device described above is performed by the device sequence control unit 41 when processing for exchanging wafers between the LC 2A or the LC 2B and the SC1 is performed. When processing for exchanging wafers between the LC 2A or the LC 2B and the mini-environment 3 is performed, it is also possible to perform the above-described processing based on the type of wafer to be conveyed to the LC.

Although it is possible to maximize a throughput depending on the type of wafer by automatically performing the above-described processing, a device user may be able to select whether to execute the above-described processing on a device GUI.

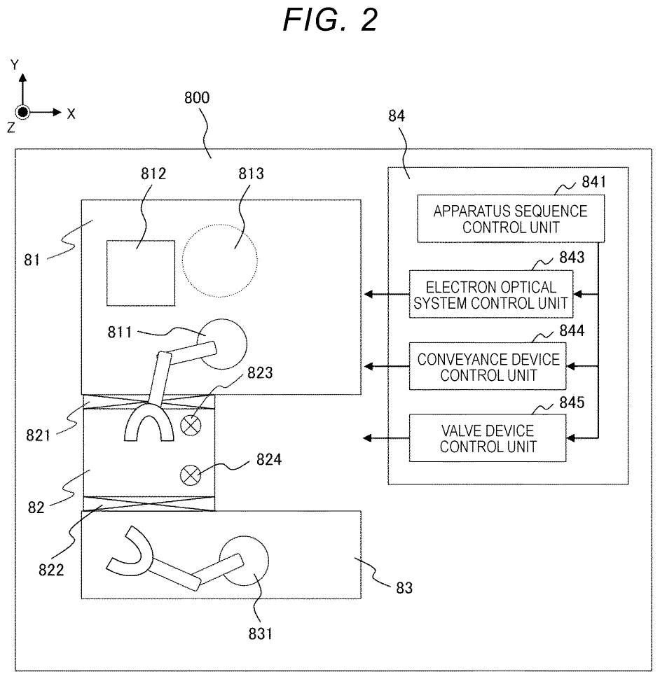

Next, to compare differences in effectiveness with the example of the invention, operations of a charged particle beam device when the invention is not applied (hereinafter referred to as the related art) will be described as a comparative example of a semiconductor measurement device with reference to FIGS. 2 to 4.

FIG. 2 is a configuration diagram showing a semiconductor measurement device of the related art. A semiconductor measurement device 800 of the related art includes an SC 81, an LC 82, a mini-environment 83, and a computer system 84.

The SC 81 includes a robot 811 that conveys a wafer, a stage device 812 that positions the wafer inside the sample chamber, and a column 813 that irradiates the wafer with a charged particle beam.

The LC 82 includes a gate valve 821 that opens and closes an opening connected to the SC 81, a gate valve 822 that opens and closes an opening connected to the mini-environment, a valve 823 that opens and closes a pipe connected to a roughing vacuum pump, and a valve 824 that opens and closes a pipe connected to a turbo molecular pump (TMP).

The computer system 84 includes a device control sequence unit 841 that controls an operation sequence of the entire device, an electron optical system control unit 843 that receives a command from the device control sequence unit 841 and controls irradiation with a charged particle beam, a conveyance device control unit 844 that controls robots 811 and 831 related to wafer conveyance and the stage device 812, and a valve device control unit 845 that controls the pressure of the LC 82.

The robot 831 that conveys a wafer is provided inside the mini-environment 83.

FIG. 3 is a flowchart showing an example of a flow of wafer conveyance in the semiconductor measurement device 800 of the related art. Operations based on the flowchart of FIG. 3 are as follows.

Step 200: The gate valve 822 is opened, and a first wafer is conveyed from the mini-environment 83 into the LC 82 using the robot 831.

Step 201: The gate valve 822 is closed, and evacuation of the LC 82 is performed to convey the first wafer, which is conveyed to the LC 82, to the SC 81 in a vacuum environment. When the evacuation is performed, the valve 823 that opens and closes the pipe connected to the roughing vacuum pump and the valve 824 that opens and closes the pipe connected to the TMP operate at an appropriate timing according to the pressure inside the LC82.

Here, as a method of setting the appropriate timing, for example, a method of measuring the pressure inside the LC 82 and performing a valve operation at a timing when the pressure falls below a preset predetermined pressure or at a timing when a preset predetermined time has elapsed is effective. Here, it is desirable that the pressure or time be set within a range that will not be affected by foreign matter scattering due to a gas flow inside the LC 82.

Step 202: When the pressure in the LC 82 drops to a value making it possible to open the gate valve 821 that opens and closes the opening connected to the SC 81, the gate valve 821 is opened, and the first wafer is conveyed onto the stage device 812 inside the SC 81 using the robot 811.

Here, as a method of setting the pressure of the LC 82 making it possible to open the gate valve 821, for example, a method of measuring the pressure inside the LC 82 and the pressure inside the SC 81 and setting the pressures so that a difference between the pressures is equal to or less than a predetermined value (for example, 0.0001 Pa) is effective. Here, it is desirable to set the pressures within a range in which the pressure inside the SC 81 does not increase significantly at the time of opening the gate valve 821.

Step 203: After step 202 is completed, pattern measurement on the first wafer is sequentially performed while operating the stage device 812 to position the first wafer. Hereinafter, the series of operations will be referred to as wafer processing.

Step 204: After step 202 is completed, the gate valve 821 is closed, and the pressure of the LC 82 is increased to near atmospheric pressure by supplying a predetermined gas, such as nitrogen, to the LC 82, in parallel with step 203.

Step 205: When the pressure of the LC 82 is increased to near atmospheric pressure, the gate valve 822 is opened, and a second wafer is conveyed from the mini-environment 83 into the LC 82 using the robot 831.

Step 206: Similarly to step 201, evacuation of the LC 82 is performed.

Step 207: After both the wafer processing started in step 203 and the evacuation of the LC 82 performed in step 206 are completed, the gate valve 821 is opened, and the second wafer (unmeasured wafer) in the LC 82 and the first wafer (measured wafer) in the SC 81 are exchanged using the robot 811.

Step 208: Similarly to step 203, wafer processing is performed on the second wafer.

Step 209: Similarly to step 204, air is supplied to the LC 82.

Step 210: When the pressure of the LC 82 is increased to near atmospheric pressure, the gate valve 822 is opened, the second wafer (measured wafer) inside the LC 82 is carried out of the device using the robot 831, and at the same time, a third wafer (unmeasured wafer) is carried into the LC 82 using the robot 831.

Step 211: Similarly to step 201, evacuation of the LC 82 is performed.

Thereafter, the processing returns to step 207 as soon as both the operations in step 208 and step 211 are completed, and the wafer processing can be performed one after another.

FIG. 4 is an example of a timing chart showing device operations in the SC 81 and the LC 82 of the charged particle beam device of the related art when the charged particle beam device of the related art is controlled using the method shown in FIG. 3.

The timing chart shows an operation of processing two wafers. The horizontal axis represents time, the upper side represents the device operation in the LC 82, the lower side represents the device operation in the SC 81, and both time axes are displayed in synchronization.

A time 500 required to exchange a wafer with the LC and a time 501 required to perform wafer processing represent times required to perform the operations of step 207 and step 208 in FIG. 2, respectively.

A time 400 required to supply air to the LC 82, a time 401 required to perform wafer exchange between the LC 82 and the mini-environment 83, and a time 402 required to perform evacuation of the LC 82 are times required to perform step 209, step 210, and step 211 in FIG. 2, respectively. 401 includes a time V1 required to open the gate valve 822 and a time V2 required to close the gate valve 822, and waiting times W1 and W2 occur in wafer processing due to vibration accompanied by an opening/closing operation of the gate valve 822. 402 includes operating times V3 and V4 of the valves 823 and 824 that open and close the pipes connected to the vacuum pump. Similarly, waiting times W3 and W4 occur in wafer processing due to vibration accompanied by the operations of the valves.

In the example shown in FIG. 4, the waiting times W1, W2, W3, and W4 occur while wafer processing of one wafer is performed, which results in a reduction in throughput.

What is claimed is:

1. A semiconductor processing apparatus comprising:
a sample chamber that includes a processing mechanism for processing a semiconductor wafer therein;
a plurality of load lock chambers that carry the semiconductor wafer into the sample chamber; and
a sample exchange mechanism that exchanges semiconductor wafers between the sample chamber and each of the plurality of load lock chambers, wherein
the semiconductor processing apparatus includes a control mechanism that controls operations of mechanisms of the plurality of load lock chambers so that an operation of a mechanism accompanied by an operation that generates vibration is performed in a load lock chamber in which the semiconductor wafer is not exchanged among the plurality of load lock chambers at a timing when one of the plurality of load lock chambers is exchanging the semiconductor wafer with the sample chamber.

2. The semiconductor processing apparatus according to claim 1, wherein the mechanism accompanied by an operation that generates vibration includes at least one of a gate valve for taking the semiconductor wafer into and out of the load lock chamber, and an opening/closing valve of a pipe connected to an adjustment mechanism for adjusting air pressure in the load lock chamber.

3. The semiconductor processing apparatus according to claim 1, wherein the processing mechanism is at least one of a mechanism that observes and/or processes a semiconductor by using a charged particle beam, and a mechanism that performs exposure by using light.

4. The semiconductor processing apparatus according to claim 2, wherein the pipe connected to the adjustment mechanism includes at least one of
a pipe for allowing a predetermined gas to flow into the load lock chamber,
a pipe connected to a roughing vacuum pump, and
a pipe connected to a turbo molecular pump.

5. The semiconductor processing apparatus according to claim 1, wherein the sample exchange mechanism conveys a sample in the sample chamber to the load lock chamber at a timing when the semiconductor wafer is carried from the load lock chamber to the sample chamber.

6. The semiconductor processing apparatus according to claim 1, further comprising:
a changing means capable of changing a timing when an operation of the mechanism accompanied by an operation that generates vibration is performed, based on at least one of a time required for processing of the semiconductor wafer and a time required for evacuation of the load lock chamber.

7. The semiconductor processing apparatus according to claim 6, wherein
the processing of the semiconductor wafer is processing for irradiating the semiconductor wafer with a charged particle beam, and
a time required for the processing is calculated from a sum of a time required to irradiate one point on the semiconductor wafer with a charged particle beam and a time required to move the semiconductor wafer to irradiate the one point with the charged particle beam, and the number of points of the semiconductor wafer which are irradiated with the charged particle beam.

8. The semiconductor processing apparatus according to claim 1, further comprising:
a first control device that controls the operation of the mechanism accompanied by an operation that generates vibration;
a second control device that controls a conveyance device conveying the semiconductor wafer;
a third control device that controls the processing mechanism processing the semiconductor wafer; and
a fourth control device that controls the operation of the entire device by transmitting control signals to the first to third control devices.

9. The semiconductor processing apparatus according to claim 8, wherein
a signal for prohibiting an operation of a mechanism designated in advance among the mechanisms accompanied by an operation generating vibration is transmitted from the fourth control device to the first control device while performing the processing in the processing mechanism that processes the semiconductor wafer,
the second and third control devices transmit completion of the processing in the processing mechanism that processes the semiconductor wafer to the fourth control device when the processing in the processing mechanism that processes the semiconductor wafer is completed, and
the fourth control device transmits, to the first control device, a signal for permitting the operation of the mechanism whose operation is prohibited and which is accompanied by an operation generating vibration.

10. The semiconductor processing apparatus according to claim 1, wherein
the conveyance device conveying the semiconductor wafer includes a conveyance robot.
